(19) United States
(12) Patent Application Publication
(10) Pub. No.: US 2017/0153540 A1
(43) Pub. Date: Jun. 1, 2017

(54) PHOTOMASK BLANK AND PHOTOMASK

(71) Applicant: CROWNINGTEK INC., Miaoli County (TW)

(72) Inventor: Chang-Ming Dai, Miaoli County (TW)

(21) Appl. No.: 14/956,132

(22) Filed: Dec. 1, 2015

(51) Int. Cl. G03F 1/50; G03F 1/76

(52) U.S. Cl. CPC G03F 1/50; G03F 1/76

(57) ABSTRACT

The present invention discloses a photomask blank comprises a transparent substrate on which exposure light is transmitted, and a black matrix resist layer. The black matrix resist layer is configured to include a carbon black dispersion, copolymer having amino group and/or copolymer having quaternary ammonium salt, organic solvent containing dispersion component, a binder resin having a carboxyl group, unsaturated monomer, and a photosensitive material of halogen light or green light in the range of 480-540 nm such that the black matrix resist layer is provided as one single layer for acting as a light-shielding film and as a photosensitive exposable film, and a surface of the black matrix resist layer is manufactured against a chemical processing operation and a mechanical scratching.

### FIELD OF THE INVENTION

The present invention relates to a photomask blank and a photomask for use in fabrication of printed circuit board (PCB), integrated circuits (IC), bumping process, LED in a micro-mechanical electronics system (MES), and in fabrication of STN/LCD displays, and more particularly to a photomask blank and a photomask using a black matrix resist layer as a light-shielding film.

### BACKGROUND OF THE INVENTION

Prior photolithographic processes involving the use of photomasks are employed in the fabrication of micro-pattern for a printed circuit board (PCB), a LED device and a STN display, by which an emulsion plate is applied with feature size up to roughly 50-20 μm. If the feature size is less than 20 μm, the emulsion plate is not able to meet patterning requirements. In detail, a Chromium film produced by stacking Cr films with thickness of 80-100 nm and CrOxNy 25 nm is formed on a photomask blank for high-density semiconductor integrated circuits such as LSI and VLSI chips, color filters of charge-coupled devices (CCD) and liquid-crystal displays (LCD), PCB, micro-mechanical electronics system (MES) and so on.

Photomasks used for microfabrication are produced from a photomask blank comprising: a transparent substrate such as quartz glass, alumina-silicate glass; and a light-shielding film, typically in form of a chromium film, which is deposited on the transparent substrate by a sputtering or vacuum evaporation technique. The light-shielding film can be alternatively in form of photosensitive halides emulsion film, which is coated on the transparent substrate by a spinning or a spraying process. The photomask is thereafter generated in a mask-house by forming a specific pattern in the light-shielding film of the photomask blank.

The photomask blank, either emulsion-based or chromium-based, must have light-shielding film with characteristic features of low light reflectance and high light exposure sensitivity with regard to a mask beam writer. In order to cope a long time period of pattern integrity in subsequent pattern copying processes, a shielding film should have mechanical, chemical, and environmental reliability. In addition, to prevent light which reflects back from the semiconductor substrate to expose and pass through the projection lens to therefore reflect again through the photomask and return to the semiconductor substrate, it it noted that a low reflection coating, such as applied by the emulsion film based photomask blank, or a low antireflective coating, such as applied by the Cr-film based photomask blank, is generally considered to form on a surface side, or on both the surface side and a back side of the light-shielding film.

In consideration of photomask cost, a chromium film based photomask generally has a two-layer and a three-layer structures in addition to the top-resist layer, in which the chromium film based photomask has an advantage of high resolution with mechanical and chemical reliability. On the other hand, halide silver emulsion based photomask has high sensitivity and excellent image quality, but its resolution is limited to 50-30 μm due to severe photographic troubles such as photo sensitivity or image contrast degradation because of silver granularity. Moreover, halide silver emulsion based photomask is not environmental friendly.

Conventionally, color filters are generally formed by black matrices having a film of metal such as chromium. This technique, which includes vapor depositing a metal such as chromium on a transparent substrate and etching the chromium layer through a step of photolithograph, provides thin, high light-shielding black matrices with high precision. However, at the same time, it has problems of high cost due to long production process and low productivity and environmental pollution of wastewater discharged by etching treatment and the like.

### SUMMARY OF THE INVENTION

The present invention is for solving the disadvantages as described above.

Accordingly, an object of the present invention is to provide a black matrix resist replacing both chromium based and halides silver based emulsion material for photomask blank.

Another object of the present invention is to improve the photoactive compound and resolution of black matrix resist, such as green and red sensitive, by providing specific wavelength sensitive photo-initiator/photoactive compounds.

The photomask blank comprises a transparent substrate on which exposure light is transmitted, and a black matrix resist layer. The black matrix resist layer is configured to include a carbon black dispersion, copolymer having amino group and/or copolymer having quaternary ammonium salt, organic solvent containing dispersion component, a binder resin having a carboxyl group, unsaturated monomer, and a photosensitive material of halogen light or green light in the range of 480-540 nm such that the black matrix resist layer is provided as one single layer for acting as a light-shielding film and as a photosensitive exposable film, and a surface of the black matrix resist layer is manufactured against a chemical processing operation and a mechanical scratching.

According to one embodiment of the present invention, the black matrix resist layer has an optical density larger than 2.5 and is photolysis by either halogen light or green light in the range of 480 nm-540 nm.

According to one embodiment of the present invention, the black matrix resist layer is coated on the transparent substrate with thickness of 0.5-6 nm and is soft baked at temperature of 80-150 degree Celsius for 30-80 minutes, and the black matrix resist layer is developed by a water based developer.

According to one embodiment of the present invention, the transparent substrate is a polished soda lime glass, an AlSi glass, a Boron float glass, a TFT glass or a pure quartz.

According to one embodiment of the present invention, a photomask fabricated by lithographically patterning the said photomask blank.

Accordingly, another objective of the present invention is to provide a photomask comprising a transparent substrate and a black matrix resist layer having patterned features.

The photomask comprising a transparent substrate on which exposure light is transmitted, and a black matrix resist layer having patterned features, wherein the black matrix resist layer is configured to include a carbon black dispersion, copolymer having amino group and/or copolymer having quaternary ammonium salt, organic solvent containing dispersion component, a binder resin having a carboxyl group, unsaturated monomer, and a photosensitive material of halogen light or green light in the range of 480-540 nm such that the black matrix resist layer is provided as one single layer for acting as a light-shielding film and as a photosensitive exposable film, and a pattern corresponding to the patterned features is formed on the transparent substrates by light passing through the patterned features in a lithography process.

According to one embodiment of the present invention, the black matrix resist layer has an optical density larger than or equal to 2.5 and is photolyzed by either halogen light or green light in the range of 480-540 nm, and is developed by a water based developer, and is baked hard at temperature over 150 degree Celsius to ensure the mechanical resistance of the black matrix resist layer from scratching.

According to one embodiment of the present invention, the carbon black dispersion, which is dispersed, is produced by using a continuous annular type bead mill.

According to one embodiment of the present invention, the black matrix resist layer having an amino group and/or quaternary ammonium salt are/is an acrylic copolymer formed by copolymerizing monomers having a number average molecular weight of 4,000 to 100,000.

According to one embodiment of the present invention, the binder resin has the carboxyl group which includes an ethylenically unsaturated group.

According to one embodiment of the present invention, the photosensitive material is sensitive to Ar+ or Nd YAG laser beam at the wavelength of 480-540 nm or halogen light at the wavelength of 350-460 mm.

According to one embodiment of the present invention, the transparent substrate is a polished soda lime glass, an AlSi glass, a Boron float glass, a TFT glass or a pure quartz.

By means of the technology of the present invention, the black matrix resist layer with carbon black dispersion can readily form patterns having thin film property and high light-shielding property by a photolithographic method in a single one layer process, and has excellent storage stability, sufficient sensitivity and resolution. Moreover, the present invention, most importantly, has a better performance than prior emulsion photomask blank by possessing a merit of low cost and environmentally friendly. Furthermore, the black matrix resist layer of the present invention has great mechanical resistance of scratches and process chemicals, and has even an out performance to the halide silver plate.

### BRIEF DESCRIPTION OF THE DRAWINGS

The structure and the technical means adopted by the present invention to achieve the above and other objects can be best understood by referring to the following detailed description of the preferred embodiments and the accompanying drawings.

The present invention employs a technique using a black matrix resist layer, which forms a black matrix resist layer using a photosensitive resin dispersed therein a light-shielding pigment (resin black matrix) and possesses a merit of low cost and no environmental pollution. In addition, a resin matrix resist layer has advantage of having exposure light photosensitive material, storage stability, high feature resolution of 5 μm, and good adhesion with substrate and high resistance to chemical and mechanical scratches.

FIG. 1 is a sectional view of a photomask blank according to one embodiment of the present invention.

FIGS. 2A-2D are schematic sectional views illustrating a photomask manufacturing method of the present invention, in which FIG. 2A shows a photomask blank on which a black matrix resist film has been formed, FIG. 2B shows the blank after the resist film has been exposed by laser beams (blue light or green light) or halogen light (i-, g-, h-line), FIG. 2C shows the black matrix resist layer being development, and FIG. 2D shows the manufactured photomask after the black matrix resist layer has been baked.

### DETAILED DESCRIPTION OF THE PREFERRED EMBODIMENTS

### Example of Photomask Black and Photomask Using Black Matrix Resist

A photomask blank is made by coating a Halogen light (i, g, h) or green light sensitive black resist over a transparent substrate as shown in the drawings. The photosensitive black resist layer has merit of patterning capability to halogen (i-, g-, h-line) and green laser light (Ar+ 488 nm and ND YAG 532 nm) light but also has advantage of light shielding function. This black photosensitive resist is specifically designed as a material with composition containing a binder resin having a carboxyl group, an ethylenically unsaturated monomer, a photopolymerization initiator, organic solvent, and specified multifunctional thiol compound. This black photosensitive resist layer can easily form a thin film or pattern with high light-shielding property by photolithographic method pattern, and has excellent light shielding and scratch resistance, storage stability, and exhibits sufficient sensitivity and resolution. The photomask blank has light shielding thin films with simple one-layered process and environmental friendly characteristic feature without requiring halides as Emulsion needed, good chemical resistance reliable, and can be produced at a high yield in mass production.

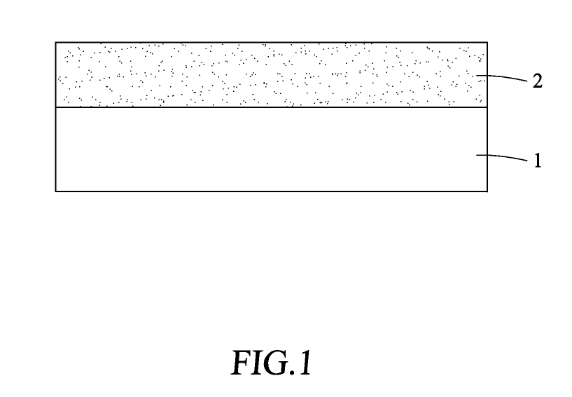

Referring to FIG. 1, the photomask blank of the present invention comprises a transparent substrate 1 on which exposure light is transmitted, and a black matrix resist film layer 2. The black matrix resist layer 2 is configured to include a carbon black dispersion, copolymer having amino group and/or copolymer having quaternary ammonium salt, organic solvent containing dispersion component, a binder resin having a carboxyl group, unsaturated monomer, and a photosensitive material of halogen light or green light in the range of 480-540 nm such that the black matrix resist layer is provided as one single layer for acting as a light-shielding film and a photosensitive exposable film. And a surface of the black matrix resist layer is manufactured against a chemical processing operations and mechanical scratching. The photosensitive material is a photosensitive initiator or a photoactive compound. The black matrix resist layer 2 is photolysis by either halogen light or green light in the range of 480 nm-540 nm, and has function of blue light or green light sensitivity, water based alkali solution developable, good light-shielding film (optical density ranged in 2.5-6.0/μm), low reflective film, acid/alkali chemical sand scratches resistance.

The transparent substrate 1 on which the black matrix resist layer 2 is coated is made of any desired material that is transparent to the exposure light, for example, a preferably pure quartz, a polished soda lime glass, an aluminosilicate glass, a TFT glass, boron fluoride or a magnesium fluoride.

The black matrix layer 2 is with thickness of 100 nm to 5 μm and the black matrix resist layer 2 is coated by spin coating or slit coating or slit and spin machines. OD (optical density) is within 1.0-6.0 by different respective thickness. Preferably, the black matrix layer 2 is with 100 to 6000 nm thickness, especially with 500 to 2000 nm thickness. And the black matrix layer 2 has low reflective which is less 20%. For example, the black matrix resist layer 2 is coated on the transparent substrate with thickness of 0.5-6 μm and is soft baked at temperature of 80-150 degree Celsius for 30-80 minutes, and the black matrix resist layer 2 is developed by a water based developer.

In the present invention, a photomask is also provided. The photomask comprising a transparent substrate 1 on which exposure light is transmitted, and a black matrix resist layer 2 having patterned features. The black matrix resist layer 2 is configured to include a carbon black dispersion, copolymer having amino group and/or copolymer having quaternary ammonium salt, organic solvent containing dispersion component, a binder resin having a carboxyl group, unsaturated monomer, and a photosensitive material of halogen light or green light in the range of 480-540 nm such that the black matrix resist layer 2 is provided as one single layer for acting as a light-shielding film and as a photosensitive exposable film. The photosensitive material is a photosensitive initiator or a photoactive compound. And a pattern corresponding to the patterned features is formed on the transparent substrate 1 by light passing through the patterned features in a lithography process.

The transparent substrate 1 is a polished soda lime glass, an AlSi glass, a Boron float glass, a TFT glass or a pure quartz.

Similarly, the black matrix resist layer 2 has an optical density larger than or equal to 2.5 and is photolyzed by either halogen light or green light in the range of 480-540 nm. The black matrix resist layer 2 is able to be developed by a water based developer, such as KOH, NaOH, and TMAH. And the black matrix resist layer 2 is baked hard at temperature over 50 degree Celsius or using IR curing to ensure the mechanical resistance of the black matrix resist layer 2 from scratching.

Furthermore, the binder resin has the carboxyl group which includes an ethylenically unsaturated group.

The photosensitive initiator or the photoactive compound is sensitive to Ar+ or Nd YAG laser beam at the wavelength of 480-540 nm or halogen light at the wavelength of 350-460 mm. And the black matrix resist layer 2 is suitable to be processed by coating in a red and yellow light environment as a light-resistant processing environment.

Furthermore, the carbon black dispersion, which is dispersed, is produced by using a continuous annular type bead mill.

Furthermore, the black matrix resist layer 2 having an amino group and/or quaternary ammonium salt are/is an acrylic copolymer formed by copolymerizing monomers having a number average molecular weight of 4,000 to 100,000.

In the present invention, a photomask fabricated by lithographically patterning the said photomask blank is provided.

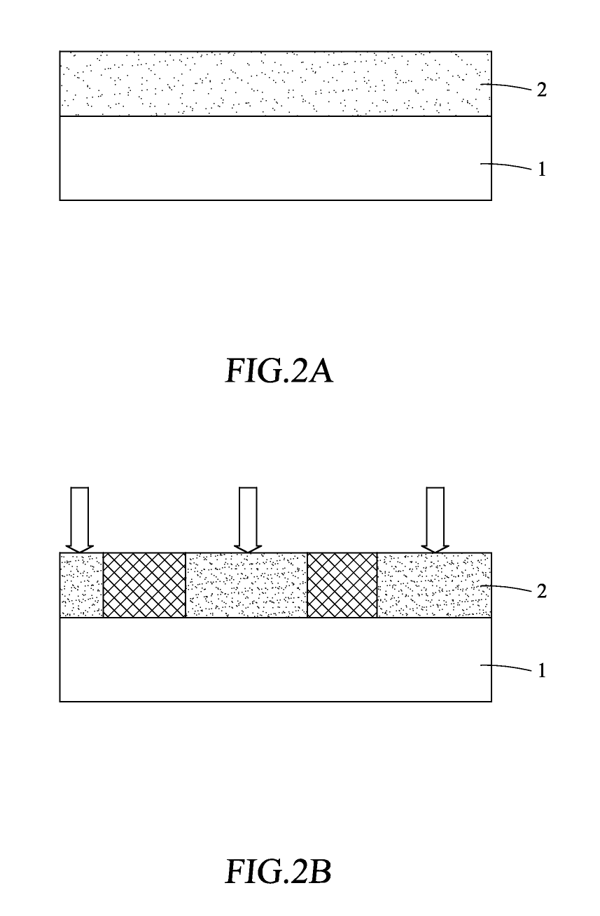

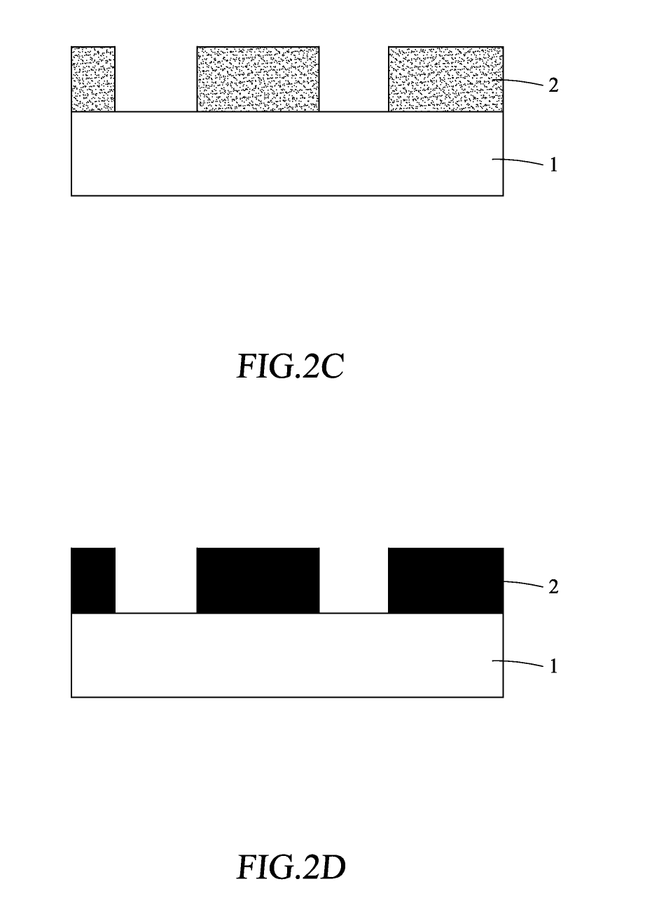

The photomask blank constructed as above is then patterned by a lithographic process to form the photomask of this one layer structure as shown in FIG. 2A to 2D.

More specifically, by using the photomask blank of FIG. 1, the photomask of FIG. 2D is manufactured by a process as shown in FIG. 2B-2D. The black matrix resist layer 2 is formed on the transparent substrate 1. The matrix resist layer 2 is then patterned (FIG. 2B-2D) by laser beam exposure of mask patterns, developing resist pattern by alkali developer, and then being hot baked to densify the black matrix resist layer 2, by which the black matrix resist layer 2 has light-shielding patterns (exposure and development) and mechanically resistance from scratches and also from alkali an acid cleaning thereafter applied.

There has been described a photomask blank having a significantly cost effective as compared to Cr-film and Emulsion based competitive materials while having better patterning resolution up to 2 μm with simplicity processes. Most importantly, this material is environmentally friendly without chromium and silver halides. The resulting photomask can accommodate higher integration in PCB, LCD, LED, TP, STN and MES patterning applications.

### Examples of the Invention are Given Below by Way of Illustration, and not by Way of Limitation

On a 20×24/24×24/24×28 inch Soda lime substrate, a black matrix resist layer 2 of 0.5-2.0 μm thick is coated by spin or slit coating machine. The black matrix resist layer 2 with viscosity of 3-10 cp is coated on polished glass substrate with thickness of 500 nm to 1500 nm as requirement of OD 3-6. In FIG. 1, the black matrix resist layer 2 is formed on the transparent substrate 1. The black matrix resist layer 2 is then patterned (FIG. 2B-2D) by laser beam exposure of mask patterns, development of black matrix resist layer 2 pattern in alkali developer, and then hot baking to densify the black matrix resist layer 2, by which the black matrix resist layer 2 is formed with light-shielding patterns (exposure and development) and mechanically resistance from scratches and from alkali an acid cleaning thereafter applied.

Compared with Cr-film and Emulsion, it is noted that the photomask of the present invention is with the black matrix resist layer 2 which significantly cost effective. Furthermore, compared with Cr-film and Emulsion, the photomask of the present invention has a better patterning resolution up to 2 μm. Most importantly, without chromium and silver halides, the material of the photomask in the present invention is environmentally friendly. As a result, the photomask can accommodate higher integration in PCB, LCD, LED, TP, STN and MES patterning.

Following example is related to the composition of black matrix resist layer 2. The black matrix resist layer 2 can function as light shielding and photosensitive to blue and green lights. For example, the black matrix resist layer 2 comprises components (A), (B), (C), (D), (E), (F), and (G) as below. Component (A) comprises a carbon black having an average primary particle diameter of 20 to 60 nm, a DBP oil absorption of 30 to 100 ml/100 g, a specific surface area by a BET method of 30 to 150 m²/g, and a concentration of carboxyl group on a particle surface of 0.2 to 1.0 μmol/m². Component (B) comprises a copolymer having an amino group and/or its quaternary ammonium salt. Component (C) comprises an organic solvent. Component (D) comprises a binder resin having a carboxyl group. Component (E) comprises an ethylenically unsaturated monomer. Component (F) comprises a photopolymerization initiator, and component (G) comprises a multifunctional thiol compound having two or more mercapto groups.

And the black matrix resist layer 2 with the components has the following ratios as 40 to 80 mass % of component (A), 4 to 50 mass % of component (B), 10 to 50 mass % of component (D), 3 to 45 mass % of component (E), 2 to 45 mass % of component (F), and 2 to 45 mass % of component (G).

Furthermore, in the dispersed carbon black matrix resist, the ratio of the carbon black and the copolymer having an amino group or its quaternary ammonium salt is in a range between 100:5 to 100:25 by mass ratio. The binder resin of carbon black dispersion composition for black matrix resist layer 2 in photomask application has a carboxyl group. The dispersed carbon black matrix resist is produced by using a continuous annular type bead mill.

The above description should be considered as only the discussion of the preferred embodiments of the present invention. However, a person skilled in the art may make various modifications without deviating from the present invention. Those modifications still fall within the spirit and scope defined by the appended claims.

What is claimed is:

1. A photomask blank, comprising:
a transparent substrate on which exposure light is transmitted; and
a black matrix resist layer,
wherein the black matrix resist layer is configured to include a carbon black dispersion, copolymer having amino group and/or copolymer having quaternary ammonium salt, organic solvent containing dispersion component, a binder resin having a carboxyl group, unsaturated monomer, and a photosensitive material of halogen light or green light in the range of 480-540 nm such that the black matrix resist layer is provided as one single layer for acting as a light-shielding film and as a photosensitive exposable film, and a surface of the black matrix resist layer is manufactured against a chemical processing operation and a mechanical scratching.

2. The photomask blank of claim 1, wherein the black matrix resist layer has an optical density larger than 2.5 and is photolysis by either halogen light or green light in the range of 480 nm-540 nm.

3. The photomask blank of claim 1, wherein the black matrix resist layer is coated on the transparent substrate with thickness of 0.5-6 nm and is soft baked at temperature of 80-150 degree Celsius for 30-80 minutes, and the black matrix resist layer is developed by a water based developer.

4. The photomask blank of claim 1, wherein the transparent substrate is a polished soda lime glass, an AlSi glass, a Boron float glass, a TFT glass or a pure quartz.

5. A photomask fabricated by lithographically patterning the photomask blank of claim 1.

6. A photomask, comprising:
a transparent substrate on which exposure light is transmitted; and
a black matrix resist layer having patterned features,
wherein the black matrix resist layer is configured to include a carbon black dispersion, copolymer having amino group and/or copolymer having quaternary ammonium salt, organic solvent containing dispersion component, a binder resin having a carboxyl group, unsaturated monomer, and a photosensitive material of halogen light or green light in the range of 480-540 nm such that the black matrix resist layer is provided as one single layer for acting as a light-shielding film and as a photosensitive exposable film, and a pattern corresponding to the patterned features is formed on the transparent substrate by light passing through the patterned features in a lithography process.

7. The photomask of claim 6, wherein the black matrix resist layer has an optical density larger than or equal to 2.5 and is photolyzed by either halogen light or green light in the range of 480-540 nm, and is developed by a water based developer, and is baked hard at temperature over 50 degree Celsius or using IR curing to ensure the mechanical resistance of the black matrix resist layer from scratching.

8. The photomask of claim 6, wherein the carbon black dispersion, which is dispersed, is produced by using a continuous annular type bead mill.

9. The photomask according to claim 6, wherein the black matrix resist layer having an amino group and/or quaternary ammonium salt are/is an acrylic copolymer formed by copolymerizing monomers having a number average molecular weight of 4,000 to 100,000.

10. The photomask of claim 6, wherein the binder resin has the carboxyl group which includes an ethylenically unsaturated group.

11. The photomask of claim 6, wherein the photosensitive material is sensitive to Ar+ or Nd YAG laser beam at the wavelength of 480-540 nm or halogen light at the wavelength of 350-460 mm.

12. The photomask of claim 6, wherein the transparent substrate is a polished soda lime glass, an AlSi glass, a Boron float glass, a TFT glass or a pure quartz.
